(19) United States
(12) Patent Application Publication
(10) Pub. No.: US 2024/0109448 A1
(43) Pub. Date: Apr. 4, 2024

(54) MONITORING ISOLATION RESISTANCE TO VALIDATE VEHICLE CHARGER FUNCTIONALITY

(71) Applicant: Rivian IP Holdings, LLC, Plymouth, MI (US)

(72) Inventors: Aashiv Vij, Los Alamito, CA (US); Steven Schulz, Torrance, CA (US); Ming Li, Torrance, CA (US); Lixiang Wei, Irvine, CA (US)

(21) Appl. No.: 17/955,747

(22) Filed: Sep. 29, 2022

(51) Int. Cl. B60L 53/62; B60L 53/14; G01R 1/20; G01R 1/28; H02J 7/00

(52) U.S. Cl. CPC B60L 53/62; B60L 53/14; G01R 1/203; G01R 1/28; H02J 7/0031

(57) ABSTRACT

Monitoring isolation resistance to validate vehicle charger functionality is provided. A system can include a first one or more resistors connected to a first terminal of a first direct current bus of a charger. The charger can be configured to deliver power to a first electric vehicle. The system can include a controller comprising circuitry. The controller can be configured to determine a resistance at the first one or more resistors. The controller can control delivery of power to the first electric vehicle responsive to a comparison of the resistance at the first one or more resistors with a threshold.

### INTRODUCTION

A vehicle, such as an electric vehicle, can be powered by batteries. The batteries can be charged by dispensers.

### SUMMARY

This disclosure is generally directed to monitoring isolation resistance to validate the functionality of a charger or dispenser of a vehicle. For example, the technology can monitor a known output isolation resistance to validate the functionality. This technical solution can allow vehicle charging systems to facilitate operation of charging dispensers using fewer hardware components while maintaining or improving the reliability and accuracy with which isolation resistance is monitored. For example, this technology can add resistors with known resistor values to the output terminals of a direct current (“DC”) bus of a vehicle charging system. An isolation monitoring device can monitor (e.g., continuously monitor, monitor based on a time interval, or monitor responsive to a condition or event) the isolation resistance values of the charging system including the resistors with the known resistance value (e.g., the insulation resistance in parallel with the added resistors). A controller can compare the measured resistance to a stored resistance value before a charging session to validate the functionality of the isolation monitoring device or to confirm whether the charging system is operating according to operating parameters. If the controller determines the measured resistance does not match the stored resistance value, the controller can block or prevent the charger from delivering power to the electric vehicle.

At least one aspect is directed to a system. The system can include a first one or more resistors connected to a first terminal of a first direct current bus of a charger, the charger configured to deliver power to a first electric vehicle. The system can include a controller comprising circuitry. The controller can be configured to determine a resistance at the first one or more resistors. The controller can be configured to control delivery of power to the first electric vehicle responsive to a comparison of the resistance at the first one or more resistors with a threshold.

At least one aspect is directed to a method. The method can include providing a first one or more resistors connected to a first terminal of a first direct current bus of a charger, the charger configured to deliver power to a first electric vehicle. The method can include determining, by a controller comprising circuitry, a resistance at the first one or more resistors. The method can include controlling, by the controller, delivery of power to the first electric vehicle responsive to a comparison of the resistance at the first one or more resistors with a threshold.

At least one aspect is directed to a charger to deliver power to electric vehicles. The charger can include a plurality of dispensers configured to deliver power to a corresponding plurality of electric vehicles, the plurality of dispensers each comprising a terminal at a direct current bus. The charger can include one or more resistors connected to the terminal of each of the plurality of dispensers. The charger can include a controller comprising circuitry configured to. The controller can be configured to determine, responsive to a connection between an electric vehicle and a dispenser of the plurality of dispensers, a resistance at the one or more resistors of the dispenser. The controller can be configured to control delivery of power to the electric vehicle responsive to a comparison of the resistance at the one or more resistors with a threshold.

At least one aspect is directed to a system. The system can include a first one or more resistors connected to a first terminal of a first direct current bus of a charger, the charger configured to deliver power to a first electric vehicle. The system can include a controller comprising circuitry. The controller can be configured to detect a connection between the first electric vehicle and the charger. The controller can be configured to, responsive to detecting the connection, determine a resistance at the first one or more resistors. The controller can be configured to cause delivery of power to the first electric vehicle responsive to a comparison of the resistance at the first one or more resistors with a stored resistance indicating the resistance at the first one or more resistors is within a threshold of the stored resistance.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. The foregoing information and the following detailed description and drawings include illustrative examples and should not be considered as limiting.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1 depicts a system to deliver power to electric vehicles, in accordance with present implementations.

FIG. 2 depicts a system to deliver power to electric vehicles, in accordance with present implementations.

FIG. 3 depicts a method of delivering power to electric vehicles, in accordance with present implementations.

FIG. 4 depicts a method of delivering power to electric vehicles, in accordance with present implementations.

FIG. 5 is a block diagram illustrating an architecture for a computer system that can be employed to implement elements of the systems and methods described and illustrated herein.

### DETAILED DESCRIPTION

Following below are more detailed descriptions of various concepts related to, and implementations of, methods, apparatuses, and systems of monitoring a known output isolation resistance to validate functionality. The various concepts introduced above and discussed in greater detail below may be implemented in any of numerous ways.

This disclosure is generally directed to monitoring a known output isolation resistance to validate functionality. Electric vehicle charging systems can include different pieces of equipment to facilitate operation of the dispensers to remain within operation parameters for the dispensers. These pieces of equipment can be complex, bulky, and consume computing or energy resource. Accordingly, electric vehicle charging systems that include such equipment can take up a large amount of space, be costly to construct and implement, or consume excessive computing or energy resources.

To address these and other technical challenges, an isolation monitoring system can be implemented or integrated into a vehicle charging system. For example, resistors with known resistor values can be added to cables connecting output terminals of a DC bus of a power module of a vehicle charging system with dispensers of the vehicle charging system. An isolation monitoring device can monitor the resistance of the cables between the power module and the different dispensers including the added resistors and the insulation resistance of the cables. A controller can compare the measured resistances to stored resistance values for the cables (e.g., values equal to insulation resistance values of the cables in parallel with the added resistors to the cables) before each charging session. The controller can do so to validate the functionality of the isolation monitoring device or to confirm whether the charging system or individual dispensers of the charging system are operating according to operating parameters. Responsive to determining a measured resistance of a cable connecting a dispenser to a terminal of the power module is within a threshold of the stored resistance value for the cable or dispenser, the controller can facilitate charging of a vehicle at the dispenser. However, responsive to determining the measured resistance does not match or is not within a threshold of the stored resistance value, the controller can prevent a charging session from beginning at the dispenser. This technical solution can allow vehicle charging systems to facilitate operation of charging dispensers using fewer hardware components while maintaining or improving the reliability and accuracy with which isolation resistance is monitored.

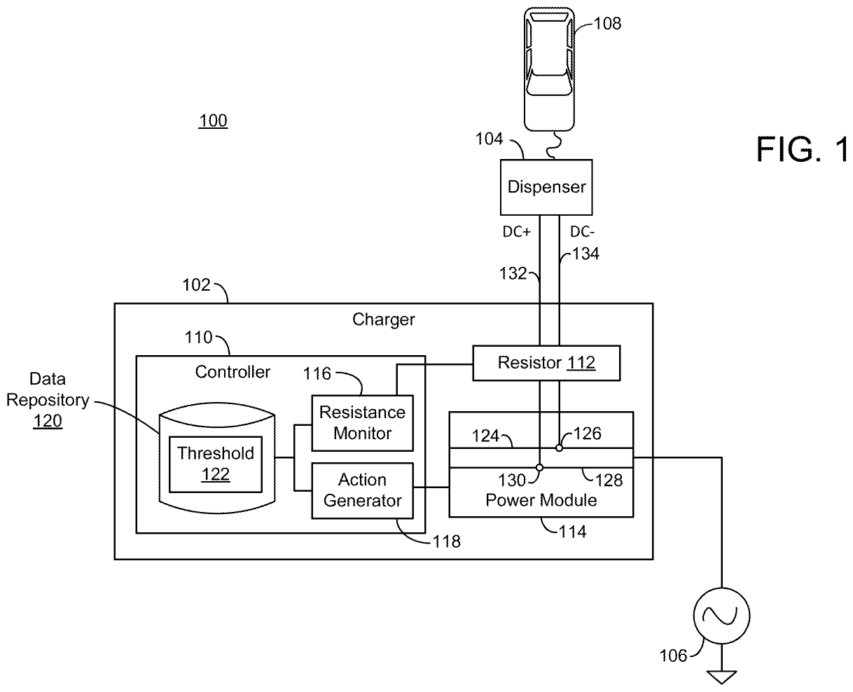

FIG. 1 depicts an example system 100, in accordance with present implementations. The system 100 can include a charger 102, a dispenser 104, and a power source 106. The charger 102 can be in communication with the dispenser 104 (e.g., communicate with the dispenser 104 over a network). The charger 102 can be, include or otherwise interface with a power cabinet that receives energy from one or more power sources (e.g., the power source 106) and distributes the energy to different dispensers 104. The dispensers 104 can deliver the energy to vehicles (e.g., a vehicle 108) connected to the dispensers to charge the vehicles. The charger 102 can measure resistances of individual buses (e.g., DC buses, such as cables) electrically connecting the charger 102 to the dispensers 104. The charger 102 can do so to determine whether the dispensers 104 can operate or are currently operating within, or otherwise in compliance with, the operating parameters of the dispensers 104 or whether the equipment measuring the resistance is operating according to predetermined operating parameters. Responsive to determining a dispenser or the measuring equipment is not or may not be able to operate according to operating parameters (or otherwise is not in compliance with predetermined or desired operating parameters) or that the measuring equipment measuring the resistance of the bus between the charger 102 and the dispenser is not operating according to operating parameters, the charger 102 can control delivery of power to a vehicle connected to the dispenser by blocking, stopping, or preventing power delivery (or energy delivery) from the charger 102 to the dispenser 104 or the vehicle 108.

The vehicle 108 can include an electric vehicle, electric truck, electric sport utility vehicle (SUV), electric delivery van, electric automobile, electric car, electric motorcycle, electric scooter, electric passenger vehicle, electric passenger or commercial truck, hybrid vehicle, or other vehicle such as sea or air transport vehicle, plane, helicopter, submarine, boat, or drone, among other possibilities. The vehicle 108 can be a fully or partially electric (e.g., plug-in hybrid) vehicle. Further, the vehicle 108 can be fully autonomous, partially autonomous, or unmanned. The vehicle 108 can also be human operated or non-autonomous.

The charger 102 can include one or more of a controller 110, resistors 112, and a power module 114. The charger 102 can be or include a container, housing, enclosure or other structure that includes one or more components that can distribute power to dispensers, such as the dispenser 104. The charger 102 can be a power cabinet (e.g., a DC power cabinet) that can provide energy (e.g., DC energy) stored from the power source 106 to the dispensers. The charger 102 can communicate with the dispensers, including the dispenser 104, via a communications interface. The communications interface can be or include an antenna or other component that allows the controller 110 of the charger 102 to communicate with the dispensers. The power module 114 can be a power module configured to store or otherwise direct energy to one or more dispensers (e.g., a single chain of dispensers including the dispenser 104). The power module 114 can deliver energy to any number of dispensers. The power module 114 can be or include one or more cells and can receive or store energy from the power source 106, which can be a renewable energy source or a utility grid. The power source 106 can be or include a single phase or a three phase alternating current (“AC”) power source. One or more rectifiers within the charger 102 can convert power from the AC power source to DC power. The converted power can be stored in the power module 114. The power source 106 can be or include a DC power source. The charger 102 can include any number of power modules that can each be connected to a different chain of dispensers.

The controller 110 can include at least one processing unit or other logic device such as a programmable logic array engine, or module configured to communicate with the dispenser 104 and the power module 114. The controller 110 can be the same or similar to the computing system 500. The controller 110 can include or control isolation resistance measuring equipment to measure the resistance at the resistors 112. In doing so, the controller 110 can measure the resistance of the resistors 112 in parallel with the insulation resistances of the buses to which the resistors 112 are connected. The controller 110 can determine an action based on the measured resistances, such as by comparing the measured resistances to a threshold and determining an action based on whether the measured resistances exceed or are less than the threshold. The controller 110 can communicate with the dispenser 104 to facilitate or block the dispenser 104 from delivering energy based on the determined action. The controller can control the power module 114 to facilitate delivering energy to the dispenser 104.

The dispenser 104 can be or include one or more dispensers that receive power from the power module 114. The dispenser 104 can be a dispenser of a daisy chain configuration of dispensers. The dispenser 104 can include any number of dispensers. The dispenser 104 can include a charge port and a charge controller. The charge port can be a port that electric vehicles can connect to and receive power through. The charge port can include one or more switches that can direct power to electric vehicles connected to the dispenser 104. The charge controller can transmit and receive signals from the controller 110 to control (e.g., control through the switches of the dispenser 104) whether to deliver energy to an electric vehicle connected to the dispenser 104.

The controller 110 can include at least one resistance monitor 116. The controller 110 can include at least one action generator 118. The controller 110 can include at least one data repository 120. The resistance monitor 116 and the action generator 118 can each include at least one processing unit or other logic device such as a programmable logic array engine, or module configured to communicate with the data repository 120 or database. The resistance monitor 116 and the action generator 118 can be separate components, a single component, or part of the controller 110. The controller 110 can include hardware elements, such as one or more processors, logic devices, circuits, or memory.

The data repository 120 can include one or more local or distributed databases, and can include a database management system. The data repository 120 can include computer data storage or memory and can store a threshold 122. The threshold 122 can be or include one or more thresholds. The threshold 122 can be or include a stored resistance value (e.g., a stored resistance value of an insulation resistance of a cable in parallel with one or more resistors of the cable). The threshold 122 can be or include a global threshold to which all measured resistances can be compared. The threshold 122 can be or include one or multiple thresholds that correspond to different dispensers (e.g., measured resistance values for buses connected to different dispensers can be compared against thresholds that correspond to the corresponding different dispensers). The thresholds can be stored with identifications of the dispensers to which the thresholds correspond. The controller 110 can compare a measured resistance value with the threshold 122 and determine whether the measured resistance value exceeds or is less than the threshold 122.

The threshold 122 can be a bound of a range. The range can be stored in the data repository 120. The range can have an upper bound and a lower bound. The controller 110 can compare a measured resistance value with the range to determine whether the measured resistance value is within the range. By comparing a measured resistance value to the threshold 122 or the range, the controller 110 can determine whether a dispenser connected to the bus from which the resistance value was measured is capable of or is operating within operating parameters of the dispenser or whether the equipment measuring the resistance is operating according to operating parameters.

The controller 110 can control the switching configurations of the charge port of the dispenser 104. For example, the controller 110 can measure the resistance of the circuitry connecting the dispenser 104 to the power module 114 for energy transfer. The controller 110 can compare the measured resistance to the threshold 122. Responsive to determining the measured resistance is outside of the threshold 122, the controller 110 can control the power module 114 to block or prevent the power module 114 from delivering energy to the dispenser 104 or transmit a message to the dispenser 104 to block the dispenser 104 from delivering energy to the vehicle 108. The dispenser 104 (e.g., via a charge controller of the dispenser 104) can receive the message and adjust the configurations of the switches to the charge ports of the dispenser 104 to stop or prevent charging the vehicle 108.

In operation, the resistance monitor 116 of the controller 110 can detect the arrival of the vehicle 108 at the dispenser 104. The resistance monitor 116 can detect the arrival of the vehicle 108 by receiving an indication from the dispenser 104. The resistance monitor 116 can receive the indication responsive to the vehicle 108 connecting to the dispenser 104. For example, the resistance monitor 116 can receive the indication responsive to a driver plugging a power cord of the dispenser 104 into the vehicle 108 to charge the vehicle 108. The indication can be an identification that an electric vehicle has connected to a dispenser. The resistance monitor 116 can receive the indication in a data packet.

Responsive to detecting the arrival of the vehicle 108 at the dispenser 104, the resistance monitor 116 can determine a resistance at the resistors 112. The resistors 112 can be or include one or more resistors that are connected to a negative direct current bus 124 at a terminal 126 or a positive direct current bus 128 at a terminal 130. The bus 124 can be a cable connecting the terminal 126 to the power source 106. The bus 128 can be a cable connecting the terminal 130 the terminal 130 to the power source 106. The resistors 112 can be coupled between the dispenser 104 and the terminals 126 and 130 by buses 134 and 132, respectively. The buses 134 and 132 can be cables connecting the dispenser 104 to the buses 124 and 128 at the terminals 126 and 130. The resistors 112 can include two resistors between the terminal 126 and the dispenser 104 or two resistors between the terminal 130 and the dispenser 104. The two resistors between the terminal 126 or the terminal 130 and the dispenser 104 can be in parallel (e.g., the resistors 112 can include two resistors in parallel with each other between the terminal 126 and the dispenser 104 or two resistors in parallel with each other between the terminal 130 and the dispenser 104). Connecting two resistors in parallel can increase redundancy in the system 100 between the dispenser 104 and the terminal 126 or the terminal 130.

The resistance monitor 116 can be, include, or operate resistance measuring equipment (e.g., isolation resistance measuring equipment) that measures the resistance at the resistors 112. The resistance monitor 116 can measure the resistance at the resistors 112 in response to receiving the indication of the arrival of the vehicle 108. The resistance monitor 116 can measure the resistance at the resistors 112 prior to the dispenser 104 or the power module 114 delivering power to the vehicle 108. To do so, the resistance monitor 116 can operate as an ohm meter and measure the resistance of the resistors 112 between the terminal 126 and the dispenser 104 or the terminal 130 and the dispenser 104. When measuring the resistance of the resistors 112 between one of the terminal 126 or the terminal 130 and the dispenser 104, the resistance monitor 116 can measure the resistance of the resistors 112 in addition to the insulation resistance of the bus 132 or the bus 134. The measurement can be a measurement of the resistance of the resistors 112 in parallel with the insulation resistance (e.g., the insulation) of the bus 132 or the bus 134. The measurement can be a measurement of two resistors of the resistors 112 in parallel with the insulation resistance of the bus 132 or the bus 134. For example, resistor A and resistor B of the resistors 112 can be connected to the bus 132 between the terminal 130 and the dispenser 104. Resistance C and resistor D of the resistors 112 can be connected to the bus 134 between the terminal 126 and the dispenser. Upon the vehicle 108 arriving at the dispenser 104 and a driver of the vehicle 108 connecting the vehicle 108 to the dispenser 104, the dispenser 104 can transmit an indication of the arrival of the vehicle 108 to the controller 110. Responsive to the controller 110 receiving the indication, the resistance monitor 116 can measure a resistance value of the resistor A and resistor B in parallel with an insulation resistance of the bus 132. The resistance monitor 116 can additionally or instead measure a resistance value of the resistor C and resistor D in parallel with an insulation resistance of the bus 134. The resistance monitor 116 can additionally or instead measure the resistance of the resistors A, B, C, and D in parallel with the insulation resistances of the buses 132 and 134.

The action generator 118 can determine an action based on the measured resistance values. To do so, the action generator 118 can retrieve the threshold 122 from the data repository 120. The action generator 118 can compare the measured resistance for the bus 132 or the bus 134 to the threshold 122. The action generator 118 can determine whether the measured resistance exceeds the threshold 122 based on the comparison.

The threshold 122 can be a lower bound of a range (e.g., a defined range). The range can have a lower bound and an upper bound. The action generator 118 can compare a measured resistance value to the range to determine whether the measured resistance value is within the range. The action generator 118 can determine actions such as triggering an alert or blocking a dispenser from delivering power to an electric vehicle responsive to determining the resistance is above the upper bound of the range or below the lower bound of the range.

The threshold 122 can be set (e.g., set by an administrator) to a value equal to a resistance (e.g., a predetermined resistance) that is equal to a resistance of one or more of the resistors 112 in parallel with an insulation resistance of the bus 132 or the bus 134. For example, the resistors 112 can include a single resistor on the bus 132. The threshold 122 can be set to be equal to a resistance of the single resistor or the single resistor in parallel with an insulation resistance of the bus 132. In another example, the resistors 112 can include a plurality of resistors in parallel with each other on the bus 132. The threshold 122 can be set to the resistance of the plurality of resistors in parallel with each other or to resistance of the plurality of resistors in parallel with an insulation resistance of the bus 132. The threshold 122 can be set to the known resistances of the cables (including the added resistors) between the charger and the different dispensers.

The threshold 122 can be set (e.g., set by an administrator) based on a resistance that is equal to a resistance (e.g., a predetermined resistance) of one or more of the resistors 112 or the one or more of the resistors 112 in parallel with an insulation resistance of the bus 132 or the bus 134. For example, the action generator 118 can store a range (e.g., a defined range). The range can be a set of resistance values (e.g., a defined number of ohms, such as 100 kohms) or a set of percentages (e.g., a defined range of percentages, such as 90%-110%). The range can be applied to the resistance (e.g., the known resistance) of the one or more resistors of the resistors 112 in parallel with the insulation resistance of the bus 132 or the bus 134 such as by setting the threshold 122 as the lower bound or upper bound of the range. For instance, an administrator can set the resistance of the one or more resistors 112 in parallel with the insulation resistance of the bus 132 or the bus 134 to be the middle of the range. For example, responsive to the resistance of one or more of the resistors 112 in parallel with the insulation resistance of the bus 132 or the bus 134 being 1 Mohm and the range being 200 kohm, the threshold 122 can be set to a lower bound 900 kohm or an upper bound of 1.1 Mohm. In another example, responsive to the resistance of one or more of the resistors 112 in parallel with the insulation resistance of the bus 132 or the bus 134 being 1 Mohm and the range being 90%-110%, the threshold 122 can be set to have a lower bound of 900 kohm or an upper bound of 1.1 Mohm.

The action generator 118 can determine an action based on the comparison. For example, the action generator 118 can compare the measured resistance for the bus 132 to the threshold 122. Responsive to determining the measured resistance for the bus 132 is below the threshold 122, the action generator 118 can determine an action by querying memory for an action that corresponds to a measured resistance being less than a threshold. An action can include, for example, triggering an alert indicating the measured resistance is below the threshold. An action can include, for example, blocking or preventing delivery of power to or through the dispenser that corresponds to the measured resistance (e.g., the dispenser 104 connected to the terminal 126 or 130 through the bus 132 or the bus 134). Triggering the alert can include generating a record (e.g., a file, document, table, listing, message, notification, etc.) including a string that indicates the resistance is less than the threshold and transmitting the record to a computing device (e.g., an administrator computing device). Blocking the dispenser can include controlling the power module 114 to prevent the power module 114 from delivering energy to the dispenser 104. Blocking the dispenser can include transmitting a message to the dispenser with instructions to stop the dispenser from delivering energy to the vehicle. The action generator 118 can determine the action to be one or both of triggering an alert or blocking the dispenser from delivering energy to a vehicle.

The action generator 118 can generate an action responsive to determining the resistance is above the threshold 122 as the lower bound of the defined range. For example, responsive to determining the measured resistance is above the threshold 122, the action generator 118 can query memory for an action that corresponds to a resistance exceeding a threshold. One example of such an action includes controlling the dispenser by transmitting a message to the dispenser with instructions to cause the dispenser to deliver energy to an electric vehicle connected to the dispenser. Another example of such an action includes not transmitting any message to the dispenser (e.g., taking no action) and allowing the dispenser to deliver energy to the vehicle connected to the dispenser. Another example of an action includes controlling the power module 114 to deliver power to the dispenser according to an energy delivery schedule stored in memory of the charger 102, as described in U.S. patent application Ser. No. 16/870,885, filed May 8, 2020, the entirety of which is incorporated by reference herein.

The action generator 118 can operate according to the determined action. For example, responsive to determining the action to be triggering an alert, the action generator 118 can generate a record including a string indicating the measured resistance is less than the threshold. The action generator 118 can transmit the record to an administrator computing device. In another example, responsive to determining the action to be blocking delivery of power, the action generator 118 can control delivery of power to the vehicle 108 by controlling the power module 114 to prevent the power module from delivering energy to the dispenser 104 or transmitting a message to the dispenser 104 with instructions to block or prevent the dispenser 104 from delivering energy to the vehicle 108. In another example, responsive to determining the action to be delivering energy to the vehicle 108, the action generator 118 can transmit a message to the dispenser 104 to cause the dispenser 104 to deliver energy to the vehicle 108 or control the power module 114 to deliver energy to the dispenser 104 to deliver to the vehicle 108.

The resistance monitor 116 can monitor the resistance between terminals of the bus 124 or the bus 128 and multiple dispensers. For example, resistors can be placed on cables between dispenser A and the buses 124 and 128 and on cables between dispenser B and the buses 124 and 128. The resistance monitor 116 can measure the resistances of the cables between the terminals of the bus 124 or the bus 128. The resistance monitor 116 can do so for each dispenser by measuring the resistance of the placed resistors in parallel with the insulation resistance of the cables electrically connecting dispensers A and B to the bus 124 or the bus 128. The resistance monitor 116 can do so at set time intervals or upon receiving indications from dispenser A or dispenser B indicating an arrival of a vehicle at the respective dispenser.

The action generator 118 can determine actions for multiple dispensers based on the measured resistances. For example, the action generator 118 can compare the measured resistance to the threshold 122 or a defined range. Responsive to determining the measured resistance between one of the dispensers and the terminals of the bus 124 or the bus 128 is lower than the threshold 122 or is outside of the defined range, the action generator 118 can generate an alert indicating the dispenser that corresponds to the resistance below the threshold 122 or is outside of the defined range and transmit the alert to an administrative device. The action generator 118 can additionally or instead control the dispenser to block or prevent the dispenser from delivering power to an electric vehicle connected to the dispenser or control the power module 114 to prevent delivering energy to the dispenser.

The action generator 118 can control more than one dispenser (e.g., concurrently, simultaneously, or sequentially) based on the measured resistances. For example, the action generator 118 can determine or generate an action for dispenser A to block or prevent dispenser A from distributing energy to a vehicle connected to dispenser A responsive to the action generator 118 determining the resistance between dispenser A and a terminal at the bus 124 or the bus 128 is below the threshold 122 or outside of a defined range. While blocking or preventing the power module 114 from delivering energy to dispenser A, the action generator 118 can determine or generate an action to control dispenser B to deliver energy to a vehicle connected to dispenser B responsive to the action generator 118 determining the resistance between dispenser B and a terminal at the bus 124 or the bus 128 is above the threshold 122 or inside of a defined range. The action generator 118 can similarly control any number of dispensers by monitoring the resistances of cables between the dispensers and terminals in the power module 114 of the charger 102. Accordingly, the action generator 118 can facilitate operation of the charger 102 to avoid delivering energy to dispensers that are not operating within operating of the dispensers or delivering energy when the resistance measuring equipment is not operating according to operating parameters.

The action generator 118 can use separate thresholds or ranges when determining actions to perform for different dispensers. For example, the data repository 120 can store different thresholds or ranges for different dispensers. Each threshold or range can be equal to or determined based on a predetermined resistance of one or more resistors on cables between terminals on the bus 124 or the bus 128 and the respective dispensers and the insulation resistance of the cables. Responsive to receiving an indication that an electric vehicle arrived at one of the dispensers, the action generator 118 can identify the dispenser that transmitted the indication (e.g., identify the dispenser based on an identifier of the dispenser in the indication or message including the indication) and retrieve the threshold or range from the data repository 120 based on the identified dispenser. The resistance monitor 116 can measure the resistance between the dispenser that transmitted the indication and the bus 124 or the bus 128. The action generator 118 can compare the measured resistance with the threshold or range. The action generator 118 can then determine an action based on the comparison. The resistance monitor 116 and the action generator 118 can similarly determine actions for any number of dispensers over time as vehicles connect to dispensers connected to the charger 102 for charging.

The controller 110 can allow delivery of power to one dispenser while blocking delivery power to another dispenser. For example, first one or more resistors can be connected to a terminal of a dispenser A and a terminal of the power module 114 and second one or more resistors can be connected to a terminal of a dispenser B and the power module 114. The resistance monitor 116 can receive an indication from dispenser A indicating that a vehicle arrived at dispenser A. Responsive to receiving the indication, the resistance monitor 116 can measure the resistance of the first one or more resistors in parallel with an insulation resistance of the cable between dispenser A and the power module 114. The action generator 118 can compare the measured resistance to a threshold (e.g., a global threshold that applies to each dispenser or a threshold the action generator 118 retrieved from memory based on the indication indicating a vehicle arrived at dispenser A). The action generator 118 can determine the measured resistance exceeds the threshold. Responsive to determining the measured resistance exceeds the threshold, the action generator 118 can allow delivery of power to the vehicle via the dispenser A. The resistance monitor 116 can receive an indication from dispenser B indicating that a vehicle arrived at dispenser B. Responsive to receiving the indication, the resistance monitor 116 can measure the resistance of the second one or more resistors in parallel with an insulation resistance of the cable between dispenser B and the power module 114. The action generator 118 can compare the measured resistance to a threshold (e.g., a global threshold or a threshold the action generator 118 retrieved based on the indication indicating a vehicle arrived at dispenser B). The action generator 118 can determine the measured resistance is less than the threshold. Responsive to determining the measured resistance is less than the threshold, the action generator 118 can block delivery of power to the vehicle connected to dispenser B. The action generator 118 can deliver power to dispenser A to deliver energy to the vehicle that arrived at dispenser A while blocking delivery of power to the vehicle that arrived at dispenser B. By operating in this manner the controller 110 can avoid shutting down the system 100 when only one charger is not operating within operating parameters and instead facilitate delivery of power to vehicles through dispensers that are operating within operating parameters.

The resistance monitor 116 can measure the resistance at the resistors 112 (e.g., the resistance of a resistor on a cable between the dispenser 104 and the terminal 126 or the terminal 130) at set time intervals. For example, the resistance monitor 116 can measure the resistance every minute or every hour. The action generator 118 can compare each measured resistance to a global threshold or a threshold stored in the data repository 120 for the dispenser 104. Responsive to determining the measured resistance is above the threshold, the action generator 118 may not take any action or otherwise allow the dispenser 104 to continue operating. Responsive to determining the measured resistance is below the threshold, the action generator 118 can generate an alert identifying the dispenser 104 and transmit the alert to an administrative device or generate and transmit an instruction to the dispenser 104 indicating not to deliver energy to vehicles that connect to the dispenser 104. The action generator 118 can generate a flag or setting indicating to block distributing energy to the dispenser 104. The action generator 118 can store the flag or setting in memory. Accordingly, responsive to receiving an indication that a vehicle arrives at the dispenser 104, the action generator 118 can identify the flag or setting and control the power module 114 prevent or stop delivering energy to the dispenser 104 or the vehicle or transmit instructions to the dispenser 104 to block the dispenser 104 from distributing power to the vehicle that connected to the dispenser 104.

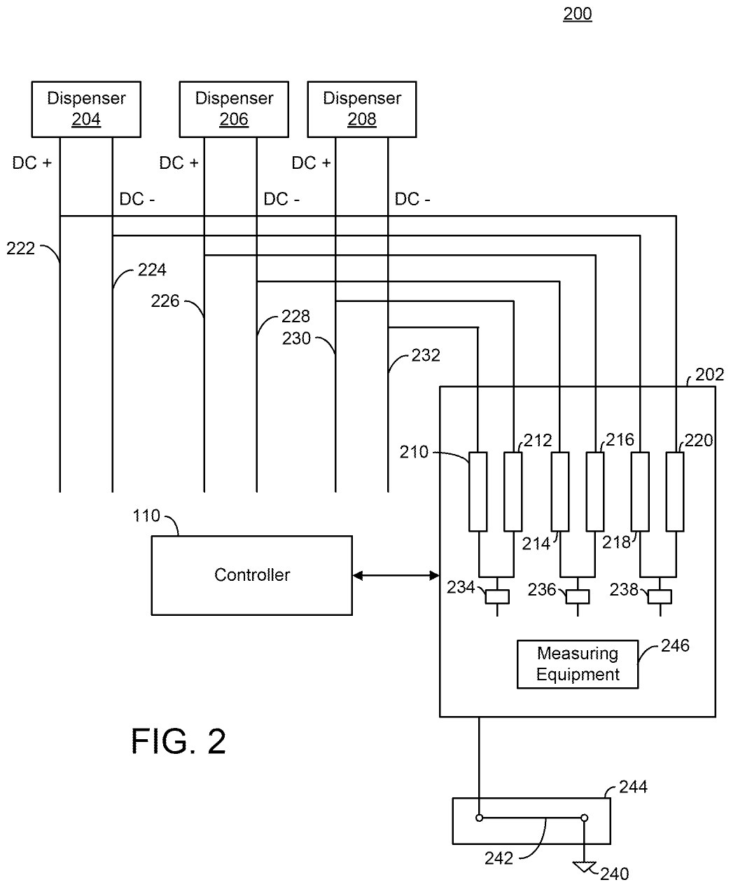

FIG. 2 depicts a system 200 to deliver power to electric vehicles, in accordance with present implementations. The system 200 can include or interface with one or more component or functionality depicted in FIG. 1, including, for example, the controller 110. The system 200 can include one or more of the controller 110, monitoring circuitry 202, and dispensers 204, 206, and 208. The monitoring circuitry 202 can be or include a printed circuit board assembly (PCBA). The monitoring circuitry 202 can be mounted onto a charger (e.g., the charger 102), such as to bus bars of the charger. The monitoring circuitry 202 can additionally or instead be mounted on to one or more of buses 222-232 of the dispensers 204, 206, 208.

The monitoring circuitry 202 can include resistors 210-220 that are electrically connected to the buses 222-232 of the dispensers 204-208. Each of the resistors 210, 212, 214, 216, 218, or 220 can include one resistor or multiple resistors in parallel. The resistor 210 can be connected to the negative bus 232, the resistor 212 can be connected to the positive bus 230, the resistor 214 can be connected to the negative bus 228, the resistor 216 can be connected to the positive bus 226, the resistor 218 can be connected to the negative bus 224, and the resistor 220 can be connected to the positive bus 222. Each of the resistors 210-220 can be respectively connected to the buses 222-232 through cables or buses. The resistors 210-220 can be connected to the cables or the buses 222-232, respectively, through the contact points 234, 236, 238. The resistors 210-220 can be connected to ground 240 through a jumper 242 that travels through a terminal block 244. The jumper 242 can connect the monitoring circuitry 202 or the resistors 210-220 to ground 240 or a power source (e.g., the power source 106). The terminal block 244 can include an insulated frame that houses the jumper 242 and the connections between the jumper 242 and ground 240 or a power source.

The circuitry 202 can include measuring equipment 246. The measuring equipment 246 can include isolation resistance measuring equipment that is configured to measure the resistance of the individual buses between the contact points 234, 236, 238 or the charger and the dispensers 204, 206, 208. The controller 110 can control the isolation resistance measuring equipment to generate such measurements at set time intervals or responsive to vehicles arriving or connecting to the dispensers 204, 206, or 208.

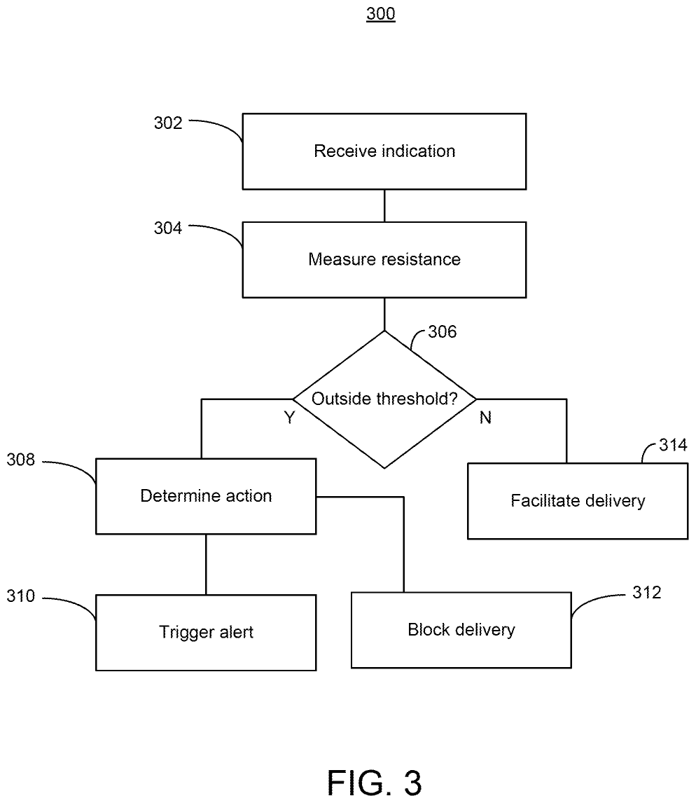

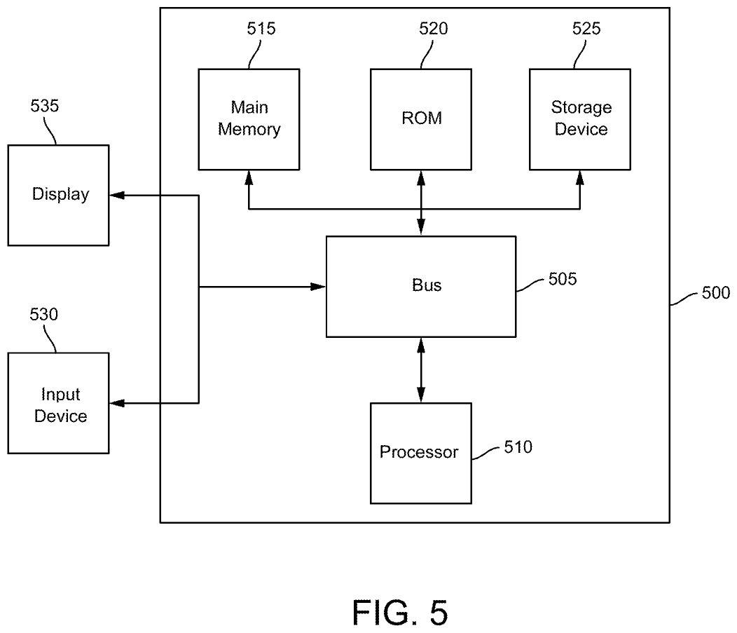

FIG. 3 depicts a method of delivering power to electric vehicles, in accordance with present implementations. The method 300 can be performed by one or more components depicted in the system 100 of FIG. 1, the system 200 depicted in FIG. 2, or the computing system 500 of FIG. 5. The method 300 can include receiving an indication (ACT 302). The method 300 can include measuring a resistance (ACT 304). The method 300 can include determining whether the measured resistance is outside of a threshold (ACT 306). The method 300 can include determining an action (ACT 308). The method 300 can include triggering an alert (ACT 310). The method 300 can include blocking delivery (ACT 312). The method 300 can include facilitating delivery (ACT 314). Performance of the method 300 can facilitate delivery of power to vehicles through different dispensers while managing the standard operation parameters of the dispensers.

At ACT 302, the method 300 can include receiving an indication of an arrival of the vehicle 108. The controller 110 can detect the arrival of the vehicle 108 at the dispenser 104. The controller 110 can receive the indication responsive to the vehicle 108 connecting to the dispenser 104. For example, the controller 110 can receive the indication responsive to a driver plugging a power cord of the dispenser 104 into the vehicle 108 to charge the vehicle 108. The indication can be an identification that the vehicle 108 has connected to the dispenser 104.

At ACT 304, the method 300 can include measuring the resistance. The controller 110 can measure the resistance of the bus 132 or the bus 134 in combination (e.g., in parallel) with the resistors 112 connected to the bus 132 or the bus 134. The controller 110 can measure the resistance in response to receiving the indication of an arrival of the vehicle 108 at the dispenser 104. The controller 110 can measure the resistance prior to delivering power to the vehicle 108. The controller 110 can measure the resistance using resistance measuring equipment (e.g., an ohmmeter or an isolation resistance monitor). For example, the controller 110 can activate resistance measuring equipment that is connected in parallel to the bus 132 or the bus 134. In response to being activated, the resistance measuring equipment can superimpose a voltage onto the bus 132 or the bus 134 and measure the resistance across the bus 132 or the bus 134 including the resistors 112 connected to the bus 132 or the bus 134 based on the superimposed voltage.

At ACT 306, the method 300 can include determining whether the measured resistance is outside of the threshold 122. The threshold 122 can be set to be equal to a predetermined or known resistance of the resistor 112 connected to the bus 132 or the bus 134. The threshold 122 can be a lower bound or an upper bound of a range of resistance values (e.g., a range of acceptable resistance values). The threshold 122 can be a threshold of a plurality of thresholds that each correspond to a different dispenser connected to the charger 102. The controller 110 can retrieve the threshold 122 for the dispenser 104 from memory based on the indication of the arrival of the vehicle 108 at the dispenser 104 including an identification of the dispenser 104. The controller 110 can compare the measured resistance value of the bus 132 or the bus 134 to the threshold 122 to determine whether the measured resistance value is outside of the threshold 122 (e.g., lower than a lower bound of a range or higher than an upper bound of a range).

Responsive to determining the measured resistance value is outside of the threshold 122, at ACT 308, the controller 110 can determine an action. The controller 110 can determine (e.g., select) the action by querying memory for actions that correspond to a measured resistance that is outside of a threshold or the threshold 122. Examples of such actions include triggering an alert indicating a measured resistance for a dispenser is outside of a threshold and blocking or preventing delivery of energy to a dispenser or a vehicle connected to the dispenser for which the measured resistance is outside of a threshold. The controller 110 can determine the action by identifying and retrieving the action (e.g., instructions that correspond to the action) from memory.

The controller 110 can determine the action based on the magnitude of a difference between the measured resistance and the threshold. For instance, the controller 110 can determine a difference between the measured resistance and threshold by comparing the measured resistance with the threshold 122. The controller 110 can compare the difference to a difference threshold (e.g., a first difference threshold). Responsive to determining the difference is less than the threshold, the controller 110 can determine the action to be to trigger an alert. Responsive to determining the difference is greater than the threshold, the controller can determine the action to be to block or prevent delivery of power to the dispenser 104 or the vehicle 108. The controller 110 can additionally compare the difference to another difference threshold (e.g., a second difference threshold) higher than the first difference threshold. Responsive to determining the difference exceeds the second difference threshold, the controller 110 can determine both actions to trigger an alert and to block delivery of power to the dispenser 104 or the vehicle 108. The controller 110 can include an indication in the alert that the difference exceeds the second difference threshold.

The controller 110 can execute or perform the determined action. For example, responsive to determining the action to be triggering an alert, at ACT 310, the controller 110 can trigger an alert. The controller 110 can trigger the alert by generating a record identifying the dispenser 104 for which the trigger is being generated, an identification of the measured resistance, or an identification of the difference between the measured resistance and one or both of the first difference threshold or the second difference threshold. The controller 110 can transmit the alert to an administrator computing device or a computer operating the vehicle 108 that arrived at the dispenser 104. In another example, responsive to determining the action to be blocking or preventing delivery of power to the dispenser 104 or the vehicle 108, at ACT 312, the controller 110 can control the power module 114 to prevent the power module 114 from delivering energy to the dispenser 104. The controller 110 can additionally or instead transmit a message to the dispenser 104 to prevent or block the dispenser 104 from delivering power to the vehicle 108 (e.g., turn off switches connecting the charge port of the dispenser 104 to the power module 114). Accordingly, the controller 110 can avoid delivering power to vehicles through dispensers that are not operating within operating parameters or alert administrators or drivers of the vehicles that the dispensers may not be used to deliver power.

However, responsive to determining the measured resistance is within the threshold 122 at ACT 306, at ACT 314, the controller 110 can facilitate delivery of power. The controller 110 can facilitate delivery of power through the dispenser 104. The controller 110 can facilitate delivery of power by allowing or controlling the power module 114 to delivery power to the vehicle 108 through the dispenser 104. The controller 110 can facilitate delivery of power by controlling the power module 114 according to a stored charging schedule. The controller 110 can facilitate delivery of power by transmitting a message to the dispenser 104 indicating to deliver power to the vehicle 108. The controller of the dispenser 104 can receive such a message and adjust any switches within the dispenser 104 to deliver power to the vehicle 108.

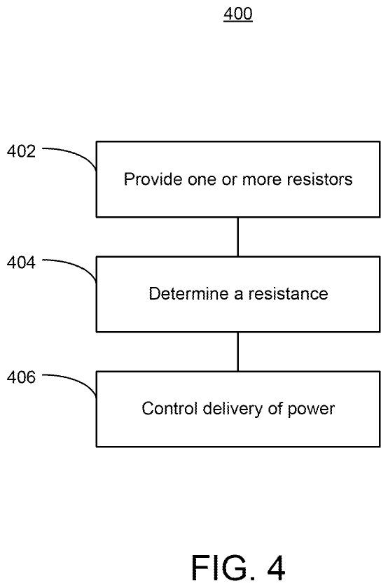

FIG. 4 depicts a method of delivering power to electric vehicles, in accordance with present implementations. The method 400 can be performed by one or more components depicted in the system 100 of FIG. 1, system 200 of FIG. 2, or the computing system 500 of FIG. 5. The method 400 can include providing one or more resistors (ACT 402). The resistor 112 can be connected to the terminal 130 of the bus 128 of the charger 102 or the terminal 126 of the bus 124 of the charger 102. The charger 102 can be configured to deliver power to the vehicle 108. The resistor 112 can be connected between the terminal 130 and the dispenser 104 via the bus 132 or between the terminal 126 and the dispenser 104 via the bus 134. The method 400 can include determining a resistance (ACT 404). The controller 110 of the charger 102 can determine the resistance at the resistor 112 by measuring the resistance of the resistor 112 in parallel with an insulation resistance of the bus 132 or the bus 132 with which the resistor 112 is connected. The method 400 can include controlling delivery of power (ACT 406). The controller 110 can control delivery of power to the vehicle 108 based on the measured resistance. For example, the controller 110 can compare the measured resistance to the threshold 122. Responsive to determining the measured resistance is less than the threshold 122, the controller can prevent the power module 114 from the delivering power to the dispenser 104 or the vehicle 108. Responsive to determining the measured resistance exceeds the threshold, the controller can allow or facilitate the power delivery from the power module 114 to the dispenser 104 or the vehicle 108. Performance of the method 400 can facilitate delivery of power to vehicles through different dispensers while managing the standard operation parameters of the dispensers.

FIG. 5 depicts an example block diagram of an example computer system 500, in accordance with some implementations. The computer system or computing device 500 can include or be used to implement a data processing system or its components. The computing system 500 includes at least one bus 505 or other communication component for communicating information and at least one processor 510 or processing circuit coupled to the bus 505 for processing information. The computing system 500 can also include one or more processors 510 or processing circuits coupled to the bus for processing information. The computing system 500 also includes at least one main memory 515, such as a random access memory (RAM) or other dynamic storage device, coupled to the bus 505 for storing information, and instructions to be executed by the processor 510. The main memory 515 can be used for storing information during execution of instructions by the processor 510. The computing system 500 can further include at least one read only memory (ROM) 520 or other static storage device coupled to the bus 505 for storing static information and instructions for the processor 510. A storage device 525, such as a solid state device, magnetic disk or optical disk, can be coupled to the bus 505 to persistently store information and instructions.

The computing system 500 can be coupled via the bus 505 to a display 535, such as a liquid crystal display, or active matrix display, for displaying information to a user such as a driver of an electric vehicle or other end user. An input device 530, such as a keyboard or voice interface can be coupled to the bus 505 for communicating information and commands to the processor 510. The input device 530 can include a touch screen display 535. The input device 530 can also include a cursor control, such as a mouse, a trackball, or cursor direction keys, for communicating direction information and command selections to the processor 510 and for controlling cursor movement on the display 535.

The processes, systems and methods described herein can be implemented by the computing system 500 in response to the processor 510 executing an arrangement of instructions contained in main memory 515. Such instructions can be read into main memory 515 from another computer-readable medium, such as the storage device 525. Execution of the arrangement of instructions contained in main memory 515 causes the computing system 500 to perform the illustrative processes described herein. One or more processors in a multi-processing arrangement can also be employed to execute the instructions contained in main memory 515. Hard-wired circuitry can be used in place of or in combination with software instructions together with the systems and methods described herein. Systems and methods described herein are not limited to any specific combination of hardware circuitry and software.

Although an example computing system has been described in FIG. 5, the subject matter including the operations described in this specification can be implemented in other types of digital electronic circuitry, or in computer software, firmware, or hardware, including the structures disclosed in this specification and their structural equivalents, or in combinations of one or more of them.

Although an example computing system has been described in FIG. 5, the subject matter including the operations described in this specification can be implemented in other types of digital electronic circuitry, or in computer software, firmware, or hardware, including the structures disclosed in this specification and their structural equivalents, or in combinations of one or more of them.

Some of the description herein emphasizes the structural independence of the aspects of the system components or groupings of operations and responsibilities of these system components. Other groupings that execute similar overall operations are within the scope of the present application. Modules can be implemented in hardware or as computer instructions on a non-transient computer readable storage medium, and modules can be distributed across various hardware or computer based components.

The systems described above can provide multiple ones of any or each of those components and these components can be provided on either a standalone system or on multiple instantiation in a distributed system. In addition, the systems and methods described above can be provided as one or more computer-readable programs or executable instructions embodied on or in one or more articles of manufacture. The article of manufacture can be cloud storage, a hard disk, a CD-ROM, a flash memory card, a PROM, a RAM, a ROM, or a magnetic tape. In general, the computer-readable programs can be implemented in any programming language, such as LISP, PERL, C, C++, C#, PROLOG, or in any byte code language such as JAVA. The software programs or executable instructions can be stored on or in one or more articles of manufacture as object code.

Example and non-limiting module implementation elements include sensors providing any value determined herein, sensors providing any value that is a precursor to a value determined herein, datalink or network hardware including communication chips, oscillating crystals, communication links, cables, twisted pair wiring, coaxial wiring, shielded wiring, transmitters, receivers, or transceivers, logic circuits, hard-wired logic circuits, reconfigurable logic circuits in a particular non-transient state configured according to the module specification, any actuator including at least an electrical, hydraulic, or pneumatic actuator, a solenoid, an op-amp, analog control elements (springs, filters, integrators, adders, dividers, gain elements), or digital control elements.

The subject matter and the operations described in this specification can be implemented in digital electronic circuitry, or in computer software, firmware, or hardware, including the structures disclosed in this specification and their structural equivalents, or in combinations of one or more of them. The subject matter described in this specification can be implemented as one or more computer programs, e.g., one or more circuits of computer program instructions, encoded on one or more computer storage media for execution by, or to control the operation of, data processing apparatuses. Alternatively or in addition, the program instructions can be encoded on an artificially generated propagated signal, e.g., a machine-generated electrical, optical, or electromagnetic signal that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. While a computer storage medium is not a propagated signal, a computer storage medium can be a source or destination of computer program instructions encoded in an artificially generated propagated signal. The computer storage medium can also be, or be included in, one or more separate components or media (e.g., multiple CDs, disks, or other storage devices include cloud storage). The operations described in this specification can be implemented as operations performed by a data processing apparatus on data stored on one or more computer-readable storage devices or received from other sources.

The terms “computing device”, “component” or “data processing apparatus” or the like encompass various apparatuses, devices, and machines for processing data, including by way of example a programmable processor, a computer, a system on a chip, or multiple ones, or combinations of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, app, script, or code) can be written in any form of programming language, including compiled or interpreted languages, declarative or procedural languages, and can be deployed in any form, including as a stand-alone program or as a module, component, subroutine, object, or other unit suitable for use in a computing environment. A computer program can correspond to a file in a file system. A computer program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform actions by operating on input data and generating output. The processes and logic flows can also be performed by, and apparatuses can also be implemented as, special purpose logic circuitry, e.g., an FPGA (field programmable gate array) or an ASIC (application specific integrated circuit). Devices suitable for storing computer program instructions and data can include non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The subject matter described herein can be implemented in a computing system that includes a back end component, e.g., as a data server, or that includes a middleware component, e.g., an application server, or that includes a front end component, e.g., a client computer having a graphical user interface or a web browser through which a user can interact with an implementation of the subject matter described in this specification, or a combination of one or more such back end, middleware, or front end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While operations are depicted in the drawings in a particular order, such operations are not required to be performed in the particular order shown or in sequential order, and all illustrated operations are not required to be performed. Actions described herein can be performed in a different order.

Having now described some illustrative implementations, it is apparent that the foregoing is illustrative and not limiting, having been presented by way of example. In particular, although many of the examples presented herein involve specific combinations of method acts or system elements, those acts and those elements can be combined in other ways to accomplish the same objectives. Acts, elements and features discussed in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular can also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation or embodiment, and references to “an implementation,” “some implementations,” “one implementation” or the like are not necessarily mutually exclusive and are intended to indicate that a particular feature, structure, or characteristic described in connection with the implementation may be included in at least one implementation or embodiment. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

Modifications of described elements and acts such as variations in sizes, dimensions, structures, shapes and proportions of the various elements, values of parameters, mounting arrangements, use of materials, colors, orientations can occur without materially departing from the teachings and advantages of the subject matter disclosed herein. For example, elements shown as integrally formed can be constructed of multiple parts or elements, the position of elements can be reversed or otherwise varied, and the nature or number of discrete elements or positions can be altered or varied. Other substitutions, modifications, changes and omissions can also be made in the design, operating conditions and arrangement of the disclosed elements and operations without departing from the scope of the present disclosure.

For example, descriptions of positive and negative electrical characteristics may be reversed. Elements described as negative elements can instead be configured as positive elements and elements described as positive elements can instead by configured as negative elements. For example, elements described as having first polarity can instead have a second polarity, and elements described as having a second polarity can instead have a first polarity. Further relative parallel, perpendicular, vertical or other positioning or orientation descriptions include variations within +/−10% or +/−10 degrees of pure vertical, parallel or perpendicular positioning. References to “approximately,” “substantially” or other terms of degree include variations of +/−10% from the given measurement, unit, or range unless explicitly indicated otherwise. Coupled elements can be electrically, mechanically, or physically coupled with one another directly or with intervening elements. Scope of the systems and methods described herein is thus indicated by the appended claims, rather than the foregoing description, and changes that come within the meaning and range of equivalency of the claims are embraced therein.

What is claimed is:

1. A system, comprising:
a first one or more resistors connected to a first terminal of a first direct current bus of a charger, the charger configured to deliver power to a first electric vehicle;
a controller comprising circuitry configured to:
determine a resistance at the first one or more resistors; and
control delivery of power to the first electric vehicle responsive to a comparison of the resistance at the first one or more resistors with a threshold.

2. The system of claim 1, wherein the first one or more resistors comprise:
a first resistor connected in parallel with a second resistor.

3. The system of claim 1, comprising:
the first one or more resistors comprising a first resistor connected in parallel with a second resistor, wherein the threshold is set equal to a predetermined resistance of the first resistor in parallel with the second resistor.

4. The system of claim 1, comprising the controller to:
measure the resistance at the first one or more resistors is less than the threshold; and
trigger an alert responsive to the resistance at the first one or more resistors being less than the threshold.

5. The system of claim 1, comprising the controller to:
determine the resistance at the first one or more resistors is less than the threshold; and
prevent delivery of power to the first electric vehicle responsive to the determination that the resistance at the first one or more resistors is less than the threshold.

6. The system of claim 1, comprising the controller to:
receive an indication that the first electric vehicle is coupled to the charger; and
measure, prior to delivery of power to the first electric vehicle and responsive to the indication, the resistance at the first one or more resistors.

7. The system of claim 1, comprising the controller to:
measure the resistance at the first one or more resistors based on a time interval.

8. The system of claim 1, wherein the charger is connected to a plurality of dispensers, comprising:
the first one or more resistors connected to the first terminal of the first direct current bus of a first dispenser of the plurality of dispensers;
a second one or more resistors connected to a second terminal of a second direct current bus of a second dispenser of the plurality of dispensers; and
the controller configured to:
control delivery of power via the first dispenser based on the comparison of the resistance at the first one or more resistors with the threshold; and
control delivery of power via the second dispenser based on a comparison of a second resistance at the second one or more resistors with a second threshold.

9. The system of claim 1, wherein the charger is connected to a plurality of dispensers, comprising:
the first one or more resistors connected to the first terminal of the first direct current bus of a first dispenser of the plurality of dispensers;
a second one or more resistors connected to a second terminal of a second direct current bus of a second dispenser of the plurality of dispensers; and
the controller configured to:
block delivery of power via the second dispenser based on a comparison of a second resistance at the second one or more resistors with a second threshold.

10. The system of claim 1, wherein the charger is connected to a plurality of dispensers, comprising:
the first one or more resistors connected to the first terminal of the first direct current bus of a first dispenser of the plurality of dispensers;
a second one or more resistors connected to a second terminal of a second direct current bus of a second dispenser of the plurality of dispensers; and
the controller configured to:
allow delivery of power via the first dispenser based on the comparison of the resistance at the first one or more resistors with the threshold;
receive an indication that a second electric vehicle is coupled to the charger via the second dispenser;
determine, prior to delivery of power to the second electric vehicle and responsive to the indication, a second resistance at the second one or more resistors; and
block delivery of power to the second electric vehicle via the second dispenser based on a comparison of the second resistance at the second one or more resistors with a second threshold, wherein the charger is configured to deliver power to the first electric vehicle via the first dispenser while delivery of power is blocked via the second dispenser.

11. A method, comprising:
providing a first one or more resistors connected to a first terminal of a first direct current bus of a charger, the charger configured to deliver power to a first electric vehicle;
determining, by a controller comprising circuitry, a resistance at the first one or more resistors; and
controlling, by the controller, delivery of power to the first electric vehicle responsive to a comparison of the resistance at the first one or more resistors with a threshold.

12. The method of claim 11, wherein the first one or more resistors comprise a first resistor connected in parallel with a second resistor.

13. The method of claim 11, wherein the first one or more resistors comprising a first resistor connected in parallel with a second resistor, wherein the threshold is set equal to a predetermined resistance of the first resistor in parallel with the second resistor.

14. The method of claim 11, comprising:
measuring, by the controller, the resistance at the first one or more resistors is less than the threshold; and
triggering, by the controller, an alert responsive to the resistance at the first one or more resistors being less than the threshold.

15. The method of claim 11, comprising:
determining, by the controller, the resistance at the first one or more resistors is less than the threshold; and
preventing, by the controller, delivery of power to the first electric vehicle responsive to the determination that the resistance at the first one or more resistors is less than the threshold.

16. The method of claim 11, comprising:
receiving, by the controller, an indication that the first electric vehicle is coupled to the charger; and
measuring, by the controller prior to delivery of power to the first electric vehicle and responsive to the indication, the resistance at the first one or more resistors.

17. The method of claim 11, wherein the charger comprises a plurality of dispensers, comprising:
providing the first one or more resistors connected to the first terminal of the first direct current bus of a first dispenser of the plurality of dispensers;
providing a second one or more resistors connected to a second terminal of a second direct current bus of a second dispenser of the plurality of dispensers;
controlling, by the controller, delivery of power via the first dispenser based on the comparison of the resistance at the first one or more resistors with the threshold; and
controlling, by the controller, delivery of power via the second dispenser based on a comparison of a second resistance at the second one or more resistors with a second threshold.

18. The method of claim 11, wherein the charger is connected to a plurality of dispensers, comprising:
providing the first one or more resistors connected to the first terminal of the first direct current bus of a first dispenser of the plurality of dispensers;
providing a second one or more resistors connected to a second terminal of a second direct current bus of a second dispenser of the plurality of dispensers; and
blocking, by the controller, delivery of power via the second dispenser based on a comparison of a second resistance at the second one or more resistors with a second threshold.

19. A system to deliver power to electric vehicles, comprising:
a plurality of dispensers configured to deliver power to a corresponding plurality of electric vehicles, the plurality of dispensers each comprising a terminal at a direct current bus;
one or more resistors connected to the terminal of each of the plurality of dispensers;
a controller comprising circuitry configured to:
determine, responsive to a connection between an electric vehicle and a dispenser of the plurality of dispensers, a resistance at the one or more resistors of the dispenser; and
control delivery of power to the electric vehicle responsive to a comparison of the resistance at the one or more resistors with a threshold.

20. The system of claim 19, comprising the controller to:
determine the resistance at the one or more resistors is less than the threshold; and
block delivery of power to the electric vehicle responsive to the determination that the resistance at the one or more resistors is less than the threshold.
